(19) United States
(12) Patent Application Publication
(10) Pub. No.: US 2025/0163322 A1
(43) Pub. Date: May 22, 2025

(54) ETCHING COMPOSITION AND METHOD FOR PRODUCING WIRING BOARD USING SAME

(71) Applicants: MITSUBISHI GAS CHEMICAL COMPANY, INC., Tokyo (JP); MITSUBISHI GAS CHEMICAL TRADING, INC., Tokyo (JP)

(72) Inventors: Satoshi TAMAI, Kanagawa (JP); Yukihide NAITO, Tokyo (JP); Kensuke OHMAE, Tokyo (JP); Hiroki TOYAMA, Tokyo (JP); Yoshiki MIYASHITA, Tokyo (JP)

(73) Assignees: MITSUBISHI GAS CHEMICAL COMPANY, INC., Tokyo (JP); MITSUBISHI GAS CHEMICAL TRADING, INC., Tokyo (JP)

(21) Appl. No.: 18/840,565

(22) PCT Filed: Feb. 22, 2023
(86) PCT No.: PCT/JP2023/006336

§ 371 Date: Aug. 22, 2024

(30) Foreign Application Priority Data
Feb. 25, 2022 (JP) 2022-027613

(51) Int. Cl. C09K 13/06; H05K 3/06

(52) U.S. Cl. CPC C09K 13/06; H05K 3/067

(57) ABSTRACT

The present invention relates to an etching composition for selectively etching a copper seed layer from a substrate that has a copper wiring pattern and the copper seed layer. An etching composition according to the present invention is used for the purpose of selectively etching a copper seed layer from a substrate that has a copper wiring pattern and the copper seed layer, and is characterized by containing (A) hydrogen peroxide, (B) sulfuric acid, (C) an azole or a salt thereof, (D) a glycol ether, (E) a halide ion and (F) water, while being also characterized in that: the content of the hydrogen peroxide (A) is 0.1 to 10% by mass based on the total amount of the etching composition; the content of the sulfuric acid (B) is 0.5 to 5% by mass based on the total amount of the etching composition; the ratio of the hydrogen peroxide (A) to the sulfuric acid (B) is 2 or more in terms of the molar ratio; and the content of the halide ion (E) is 0.01 to 3 ppm based on the total amount of the etching composition.

### TECHNICAL FIELD

The present invention relates to an etching composition for selectively etching a copper seed layer from a substrate having a copper wiring pattern and the copper seed layer, and to a method for producing a wiring board using the same.

### BACKGROUND ART

In recent years, there has been a growing need to improve the fabrication and precision of fine metal wiring for producing boards and the like for smartphones and wearable devices.

Semi-additive process (SAP, hereinafter referred to as “SAP”), in which copper wiring pattern is formed only where necessary by electrolytic copper plating, is known as a fabrication method that can be applied to finer metal wiring. Especially, modified semi-additive process (M-SAP, hereinafter referred to as “M-SAP”), which can also be applied to finer pitch pattern, has been attracting attention in recent years.

In SAP, an electroless copper plating film and, in some cases, an even thinner electrolytic copper plating film, is first formed on an insulating layer to form a copper seed layer. Next, a resist pattern for forming copper wiring is formed on the copper seed layer using a photoresist, and a copper wiring pattern is formed between the resist pattern by electrolytic copper plating. The resist pattern is then removed and the exposed copper seed layer is removed by chemical etching to form a fine copper wiring pattern on the insulating layer.

In M-SAP, an electrolytic copper foil is first laminated on an insulation layer using an electrolytic copper foil with a carrier foil, then this electrolytic copper foil is half-etched to form an ultra-thin copper layer as necessary, and an electroless copper plating film is formed thereon, thereby forming a copper seed layer. Next, a resist pattern for forming copper wiring is formed on the copper seed layer, and a copper wiring pattern is formed between the resist pattern by electrolytic copper plating. The resist pattern is then removed and the exposed copper seed layer is removed by chemical etching to form a fine copper wiring pattern on the insulating layer.

Accordingly, in SAP or M-SAP, it is necessary to remove the copper seed layer after forming the copper wiring pattern, but the height and width of the copper wiring are easily reduced when the copper seed layer is removed and the shape of the wiring cross-section may not retain its rectangularity.

Patent literature 1 describes that an etchant containing hydrogen peroxide and sulfuric acid as the main ingredients and an azole as an additive can suppress thinning and footing of the circuit part upon removing the copper seed layer in SAP. However, in order to improve the fabrication precision, more selective etching of the copper seed layer is required.

Embedded trace substrate (ETS) process (hereinafter referred to as “ETS process”) is also known as a fabrication method that can be applied to finer copper wiring (Patent literature 2). However, even in the case of ETS process, after a copper wiring pattern formed on an electrolytic copper foil as a copper seed layer is embedded in a resin, the electrolytic copper foil as the copper seed layer needs to be removed by etching, and the shape of the wiring cross-section may not retain its rectangularity depending on the degree of etching of the copper wiring along the side wall of the interlayer insulating resin (side etching) and etching of the top surface of the copper wiring during the etching process. Therefore, it is also required in ETS process to selectively etch an electrolytic copper foil as a copper seed layer.

### CITATION LIST

### Patent Literature

Patent literature 1: Japanese Unexamined Patent Application Publication No. 2006-009122
Patent literature 2: International Publication WO2019/208461

### SUMMARY OF INVENTION

### Technical Problem

Under these circumstances, there is a need to provide an etching composition for selectively etching a copper seed layer from a substrate having a copper wiring pattern and the copper seed layer.

Herein, a “copper seed layer” refers to a thin copper film that is formed as a base layer when forming copper wiring on an insulation layer by a plating technique, and its formation method is not particularly limited. The thin copper film may be, for example, any of an electrolytic copper foil, an electrolytic copper plating film, an electroless copper plating film, or any combination of them.

### Solution to Problem

The present invention relates to an etching composition shown below and to a method for producing a wiring board using the same.

[1] An etching composition for selectively etching a copper seed layer from a substrate having a copper wiring pattern and the copper seed layer, comprising:
hydrogen peroxide (A); sulfuric acid (B); an azole or a salt thereof (C); a glycol ether (D); a halide ion (E); and water (F), wherein
the content of the hydrogen peroxide (A) is 0.1-10 mass % based on the total amount of the etching composition,
the content of the sulfuric acid (B) is 0.5-5 mass % based on the total amount of the etching composition,
the ratio of the hydrogen peroxide (A) to the sulfuric acid (B) is 2 or greater in terms of a molar ratio, and
the content of the halide ion (E) is 0.01-3 ppm based on the total amount of the etching composition.

[2] The etching composition according to [1] above, wherein the azole is a heterocyclic compound having a five-membered heterocyclic ring with two nitrogen atoms or a fused heterocyclic ring thereof.

[3] The etching composition according to [2] above, wherein the azole is at least one selected from the group consisting of a pyrazole group, an imidazole group, and a benzimidazole group.

[4] The etching composition according to [3] above, wherein the azole is one or more selected from the group consisting of compounds represented by the following formulae:

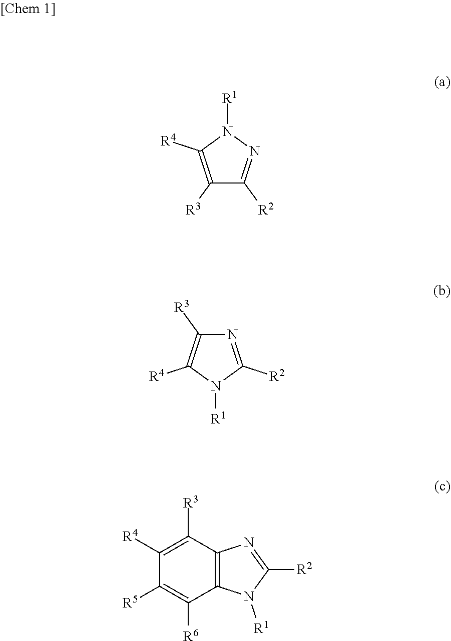

wherein R¹, R², R³, R⁴, R⁵ and R⁶ each independently represent a hydrogen atom, a C₁-C₆ alkyl group, a C₆-C₁₀ aryl group, a carboxyl group, a carboxy C₁-C₆ alkyl group, a nitro group, a hydroxyl group, a C₂-C₇ carboxylic ester, or a halogen atom.

[5] The etching composition according to [4] above, wherein the azole is at least one selected from the group consisting of imidazole, 1,2,4,5-tetramethylimidazole, 4-methyl-2-phenylimidazole, benzimidazole, 1-methylbenzimidazole, 2-methylbenzimidazole, 5-methylbenzimidazole, 2,5-dimethylbenzimidazole, 5-nitrobenzimidazole, pyrazole, and 3,5-dimethylpyrazole,

[6] The etching composition according to any one of [1] through [5] above, wherein the content of the azole is 0.01-0.5 mass % based on the total amount of the etching composition.

[7] The etching composition according to any one of [1] through [6] above, wherein the glycol ether (D) is at least one selected from the group consisting of ethylene glycol monobutyl ether, diethylene glycol monomethyl ether, diethylene glycol monophenyl ether, and dipropylene glycol monomethyl ether.

[8] The etching composition according to any one of [1] through [7] above, wherein the content of the glycol ether (D) is 0.01-1 mass % based on the total amount of the etching composition.

[9] The etching composition according to any one of [1] through [8] above, wherein the halide ion (E) is a chloride ion.

[10] The etching composition according to any one of [1] through [9] above, wherein the etching rate ratio with respect to the wiring height of the copper wiring as defined by formula (1) at a process temperature of 30° C. is 1.2 or less:

Etching rate ratio with respect to wiring height=ΔHeight/Thickness of seed layer (1)
wherein thickness of seed layer refers to the thickness (μm) of the copper seed layer removed by etching, and Δheight refers to the etch thickness (μm) of the top surface of the copper wiring removed by etching after the just etching time, i.e., the exact time required to completely remove the copper seed layer by etching.

[11] The etching composition according to above, wherein the etching rate ratio with respect to the wiring width of the copper wiring as defined by formula (2) at a process temperature of 30° C. is 1.4 or less:

Etching rate ratio with respect to wiring width=ΔWidth on one side/Thickness of seed layer (2)
wherein thickness of seed layer refers to the thickness (μm) of the copper seed layer removed by etching, and Δwidth on one side refers to the value (μm) obtained by converting the width of the copper wiring removed by etching after the just etching time, i.e., the exact time required to completely remove the copper seed layer by etching, into the width on one side (½).

[12] The etching composition according to any one of [1] through above, wherein the copper seed layer is at least one selected from the group consisting of an electrolytic copper foil, an electrolytic copper plating film, and an electroless copper plating film.

[13] A method for producing a wiring board, comprising a step of selectively etching a copper seed layer from a substrate having a copper wiring pattern and the copper seed layer using the etching composition according to any one of [1] through above.

[14] The method for producing a wiring board according to above, wherein the copper seed layer is at least one selected from the group consisting of an electrolytic copper foil, an electrolytic copper plating film, and an electroless copper plating film.

[15] A method for producing a wiring board, comprising forming a wiring circuit by selectively etching a copper seed layer from a substrate having a copper wiring pattern and the copper seed layer using the etching composition according to any one of [1] through above in semi-additive process (SAP), modified semi-additive process (M-SAP), or embedded trace substrate process (ETS process).

### ADVANTAGEOUS EFFECTS OF INVENTION

According to the present invention, there is provided an etching composition for selectively etching a copper seed layer from a substrate having a copper wiring pattern and the copper seed layer. The etching composition of the present invention can be advantageously used in SAP, M-SAP or ETS process for producing a wiring board with a wiring circuit consisting of a fine copper wiring pattern. According to a preferred aspect of the present invention, it is possible to selectively remove the copper seed layer while suppressing the thinning of the copper wiring and retaining the rectangularity of the wiring cross-section.

### BRIEF DESCRIPTION OF DRAWINGS

FIG. 1 A view illustrating a method for producing a wiring board, the method comprising forming a wiring circuit by selectively etching a copper seed layer from a substrate having a copper wiring pattern and the copper seed layer in SAP.

FIG. 2 A view illustrating a method for producing a wiring board, the method comprising forming a wiring circuit by selectively etching a copper seed layer from a substrate having a copper wiring pattern and the copper seed layer in M-SAP.

FIG. 3 A view illustrating a method for producing a wiring board, the method comprising forming a wiring circuit by selectively etching a copper seed layer from a substrate having a copper wiring pattern and the copper seed layer in ETS process.

FIG. 4 Views showing specific examples of the evaluation criteria for the rectangularity of copper wiring after the etching process.

### DESCRIPTION OF EMBODIMENTS

### 1. Etching Composition

An etching composition according to the present invention is an etching composition for selectively etching a copper seed layer from a substrate having a copper wiring pattern and the copper seed layer, comprising:
hydrogen peroxide (A); sulfuric acid (B); an azole or a salt thereof (C); a glycol ether (D); a halide ion (E); and water (F), wherein
the content of the hydrogen peroxide (A) is 0.1-10 mass % based on the total amount of the etching composition,
the content of the sulfuric acid (B) is 0.5-5 mass % based on the total amount of the etching composition,
the ratio of the hydrogen peroxide (A) to the sulfuric acid (B) is 2 or greater in terms of a molar ratio, and
the content of the halide ion (E) is 0.01-3 ppm based on the total amount of the etching composition.

Hereinafter, each component will be described.

### [Hydrogen Peroxide (A)]

According to the present invention, hydrogen peroxide (A) (hereinafter sometimes simply referred to as component (A)) is a component that serves as an oxidant of copper.

Component (A) is not particularly limited and any of the various grades can be used, including those for industrial and electronic applications. Generally, it is preferably used as an aqueous hydrogen peroxide solution from the standpoint of availability and ease of operation.

The content of component (A) is in the range of 0.1-10 mass %, preferably in the range of 0.5-8 mass %, more preferably 1-7.5 mass %, and still more preferably 2-7 mass %, based on the total amount (mass) of the etching composition. As long as the content of component (A) is within the above range, the copper seed layer can be selectively removed while suppressing the thinning of the copper wiring and retaining the rectangularity of the wiring cross-section.

Where a range of numerical values is specified herein, the upper and lower limits may be combined as appropriate, and any range of numerical values so obtained shall deemed to be disclosed.

### [Sulfuric Acid (B)]

According to the present invention, sulfuric acid (B) (hereinafter sometimes simply referred to as component (B)) is a component that acts as an etching agent for copper oxidized by the hydrogen peroxide (A).

The content of component (B) is in the range of 0.5-5 mass %, preferably in the range of 1-5 mass %, more preferably 2-5 mass %, and still more preferably 2.5-5 mass %, based on the total amount (mass) of the etching composition. As long as the content of component (B) is within the above range, the copper seed layer can be selectively removed while suppressing the thinning of the copper wiring and retaining the rectangularity of the wiring cross-section.

In the etching composition of the present invention, the ratio of the hydrogen peroxide (A) to the sulfuric acid (B) (components (A)/(B)) in terms of a molar ratio is 2 or greater, preferably 2.0 or greater, more preferably in the range of 2-20, still more preferably 2.0-20, yet still more preferably 3-15, even more preferably 3.5-10, and particularly preferably 3.5-8. By controlling the mix ratio of components (A) and (B), the copper seed layer can be selectively removed while suppressing the thinning of the copper wiring and retaining the rectangularity of the wiring cross-section.

### [Azole or Salt Thereof (C)]

According to the present invention, an azole or a salt thereof (C) (hereinafter sometimes simply referred to as component (C)) can have a function of selectively removing the copper seed layer by adsorbing onto the surface of the copper wiring.

According to the present invention, the azole is a heterocyclic compound having a five-membered heterocyclic ring with one or more nitrogen atoms or a fused heterocyclic ring thereof, wherein the atoms constituting said five-membered heterocyclic ring or fused heterocyclic ring may have one or two or more types of substituents selected from an alkyl group, a carboxyl group, a carboxyalkyl group, a nitro group, a hydroxyl group, a carboxylic ester, and a halogen atom.

Examples of the azole include a pyrazole group, an imidazole group, a benzimidazole group, a triazole group, and a tetrazole group. Among them, from the viewpoint of being able to selectively etch a copper seed layer with respect to copper wiring, the azole is preferably a heterocyclic compound having a five-membered heterocyclic ring with two nitrogen atoms or a fused heterocyclic ring thereof, and, in particular, more preferably at least one selected from the group consisting of a pyrazole group, an imidazole group, and a benzimidazole group.

Component (C) may be a salt of an azole. While the salt of an azole is not particularly limited, it is preferably an inorganic acid salt such as nitrate, sulfate, and hydrochloride from an economic point of view. When the salt of an azole is hydrochloride, the chloride ion of the hydrochloride can serve as a halide ion (E).

### <Pyrazole Group>

The pyrazole group is not particularly limited as long as it has a pyrazole skeleton, and it is preferably, for example, one or more selected from the group consisting of compounds represented by the formula below:

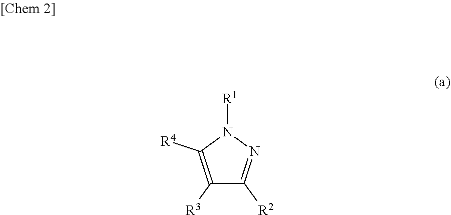

wherein R¹, R², R³ and R⁴ each independently represent a hydrogen atom, a C₁-C₆ alkyl group, a C₆-C₁₀ aryl group, a carboxyl group, a carboxy C₁-C₆ alkyl group, a nitro group, a hydroxyl group, a C₂-C₇ carboxylic ester, or a halogen atom.

Herein, a “C₁-C₆ alkyl group” refers to an alkyl group with 1-6 carbon atoms. Examples of the C₁-C₆ alkyl group include a methyl group, an ethyl group, a propyl group, an isopropyl group, a n-butyl group, a sec-butyl group, a tert-butyl group, a pentyl group, and a hexyl group. Among them, a methyl group and an ethyl group are preferred.

A “C₆-C₁₀ aryl group” refers to an aryl group with 6-10 carbon atoms. Examples of the C₆-C₁₀ aryl group include a phenyl group, a 1-naphthyl group, a 2-naphthyl group, an indenyl group, a biphenyl group, an anthryl group, and a phenanthryl group. Among them, a phenyl group is preferred.

A “carboxy C₁-C₆ alkyl group” refers to an alkyl group with 1-6 carbon atoms, having a carboxyl group. Examples of the C₁-C₆ alkyl groups include those mentioned above. As specific examples of the carboxy C₁-C₆ alkyl group, a carboxymethyl group (—CH₂—COOH) and a carboxyethyl group (—CH₂CH₂—COOH) are preferred.

A “C₂-C₇ carboxylic ester” refers to a group represented by —COOR (wherein R represents a C₁-C₆ alkyl group). Examples of the C₁-C₆ alkyl groups include those mentioned above. As specific examples of the C₂-C₇ carboxylic ester, methyl carboxylate and ethyl carboxylate are preferred.

A “halogen atom” may be any of a fluorine atom, a chlorine atom, a bromine atom, and an iodine atom, with a chlorine atom and a bromine atom being particularly preferred.

In formula (a), R¹, R², R³ and R⁴ are preferably each independently a hydrogen atom or a C₁-C₆ alkyl group.

Examples of the pyrazole group include pyrazole and 3,5-dimethylpyrazole.

### <Imidazole Group>

The imidazole group is not particularly limited as long as it has an imidazole skeleton, and it is preferably, for example, one or more selected from the group consisting of compounds represented by the formula below:

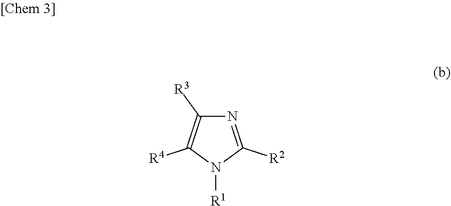

wherein R¹, R², R³ and R⁴ each independently represent a hydrogen atom, a C₁-C₆ alkyl group, a C₆-C₁₀ aryl group, a carboxyl group, a carboxy C₁-C₆ alkyl group, a nitro group, a hydroxyl group, a C₂-C₇ carboxylic ester, or a halogen atom.

In formula (b), R¹, R², R³ and R⁴ are preferably each independently a hydrogen atom, a C₁-C₆ alkyl group, or a phenyl group.

Examples of the imidazole group include imidazole, 1,2,4,5-tetramethylimidazole, and 4-methyl-2-phenylimidazole.

### <Benzimidazole Group>

The benzimidazole group is not particularly limited as long as it has a benzimidazole skeleton, and it is preferably, for example, one or more selected from the group consisting of compounds represented by the formula below:

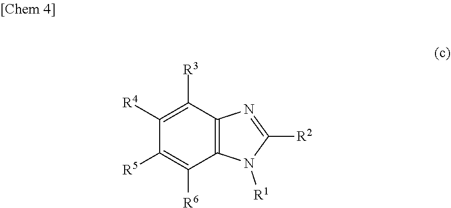

wherein R¹, R², R³, R⁴, R⁵ and R⁶ each independently represent a hydrogen atom, a C₁-C₆ alkyl group, a C₆-C₁₀ aryl group, a carboxyl group, a carboxy C₁-C₆ alkyl group, a nitro group, a hydroxyl group, a C₂-C₇ carboxylic ester, or a halogen atom.

In formula (c), R¹, R², R³, R⁴, R⁵ and R⁶ are preferably hydrogen atoms, C₁-C₆ alkyl groups or nitro groups.

Examples of the benzimidazole group include benzimidazole, 1-methylbenzimidazole, 2-methylbenzimidazole, 5-methylbenzimidazole, 2,5-dimethylbenzimidazole, and 5-nitrobenzimidazole nitrate.

### <Triazole Group>

The triazole group is not particularly limited as long as it has a triazole skeleton. Examples include 1,2,4-triazole.

### <Benzotriazole Group>

The benzotriazole group is not particularly limited as long as it has a benzotriazole skeleton. Examples include 1H-benzotriazole and 5-methyl-1H-benzotriazole.

### <Tetrazole Group>

The tetrazole group is not particularly limited as long as it has a tetrazole skeleton. Examples include 1H-tetrazole, 5-methyl-1H-tetrazole, 5-phenyl-1H-tetrazole, and 1,5-pentamethylenetetrazole.

Among the azoles mentioned above, at least one selected from the group consisting of imidazole, 1,2,4,5-tetramethylimidazole, 4-methyl-2-phenylimidazole, benzimidazole, 1-methylbenzimidazole, 2-methylbenzimidazole, 5-methylbenzimidazole, 2,5-dimethylbenzimidazole, 5-nitrobenzimidazole, pyrazole and 3,5-dimethylpyrazole is preferred, and at least one selected from the group consisting of 4-methyl-2-phenylimidazole, benzimidazole, 1-methylbenzimidazole, 2-methylbenzimidazole, 5-methylbenzimidazole, 2,5-dimethylbenzimidazole, 5-nitrobenzimidazole, and pyrazole is particularly preferred.

As mentioned above, component (C) may be a salt of an azole. Component (C) is particularly preferably at least one selected from the group consisting of 4-methyl-2-phenylimidazole, benzimidazole, 1-methylbenzimidazole, 2-methylbenzimidazole, 5-methylbenzimidazole, 2,5-dimethylbenzimidazole, 5-nitrobenzimidazole nitrate, and pyrazole.

One type of component (C) may be used alone, or two or more types of components (C) may be used in combination.

The content of the azole is preferably in the range of 0.01-0.5 mass % (100-5,000 ppm), more preferably in the range of 0.05-0.4 mass % (500-4,000 ppm), still more preferably 0.1-0.3 mass % (1,000-3,000 ppm), and particularly preferably 0.15-0.25 mass % (1,500-2,500 ppm), based on the total amount (mass) of the etching composition. As long as the content of the azole is within the above range, the copper seed layer can be selectively removed while suppressing the thinning of the copper wiring and retaining the rectangularity of the wiring cross-section. When a salt of an azole is used as component (C), the azole content above should be calculated in terms of the azole content without the salt portion. When two or more types of components (C) are used, the total amount of azoles contained in them should be within the above range.

### [Glycol Ether (D)]

According to the present invention, a glycol ether (D) (hereinafter sometimes simply referred to as component (D)) can have the effect of making the amount of copper dissolved within the plane and/or on the top and bottom sides of the substrate to be uniform during the etching process. Specifically, it can have the effect of making the etching rate and etching amount of the copper wiring within the plane and/or on the top and bottom sides of the substrate to be uniform during the etching process. Therefore, it is possible to achieve the effect of making the degree of thinning of the copper wiring within the plane and/or on the top and bottom sides of the substrate and the rectangularity of the wiring cross-section to be uniform.

While component (D) is not particularly limited, it is preferably at least one selected from the group consisting of ethylene glycol monobutyl ether, diethylene glycol monomethyl ether, diethylene glycol monophenyl ether, and dipropylene glycol monomethyl ether.

The content of component (D) is preferably in the range of 0.01-1 mass % (100-10,000 ppm), more preferably in the range of 0.05-0.75 mass % (500-7,500 ppm), and still more preferably 0.1-0.5 mass % (1,000-5,000 ppm), based on the total amount (mass) of the etching composition. As long as the content of component (D) is within the above range, the copper seed layer can be selectively removed while suppressing the thinning of the copper wiring and retaining the rectangularity of the wiring cross-section. Moreover, according to a preferred aspect of the present invention, the effects of the physical conditions such as spray pressure during the etching process are less likely to be caused when the content of component (D) is within the above range. When two or more types of components (D) are used, the total amount of them should be within the above range.

### [Halide Ion (E)]

According to the present invention, a halide ion (E) (hereinafter sometimes simply referred to as component (E)) has an effect of stabilizing the etching rate.

Component (E) is preferably a fluoride ion, a chloride ion, a bromide ion, or an iodide ion, more preferably a chloride ion or a bromide ion, and particularly preferably a chloride ion.

Examples of a source of component (E) (hereinafter sometimes referred to as a halide ion source) include acids such as hydrochloric acid and hydrobromic acid; and salts such as sodium chloride, ammonium chloride, calcium chloride, potassium chloride, potassium bromide, sodium fluoride, potassium iodide, copper(II) chloride, and copper(II) bromide. Among them, the source is preferably at least one selected from the group consisting of hydrochloric acid and sodium chloride.

For example, when the azole or the salt thereof (C) is a halide salt, component (E) may be supplied from component (C). In this case, component (C) can also be used as a halide ion source.

In the present invention, since copper dissolves when the copper seed layer is etched, copper ions can be added in advance for the purpose of suppressing fluctuations in the copper concentration in the etching composition, and copper(II) chloride and copper(II) bromide can be used to serve as both the halide ion source and the copper ion source.

One type of halide ion (E) may be used alone, or two or more types of halide ions (C) may be used in combination.

The content of component (E) is in the range of 0.01-3 ppm, preferably in the range of 0.05-2 ppm, and more preferably 0.1-1 ppm, based on the total amount (mass) of the etching composition. As long as the content of component (E) is within the above range, the etching rate can be stabilized and the copper seed layer can be selectively removed while suppressing the thinning of the copper wiring and retaining the rectangularity of the wiring cross-section. When two or more types of halide ions (E) are used, the total amount of component (E) derived therefrom should be within the above range.

### [Water (F)]

While water (F) used in the present invention (hereinafter sometimes simply referred to as component (F)) is not particularly limited, it is preferably water from which metal ions, organic impurities, particles, etc. have been removed by distillation, ion exchange process, filtering, various adsorption processes, and particularly preferably pure water or ultrapure water. The water content is the remainder of other components and is not particularly limited, but it is preferably in the range of 85-99 mass % based on the total amount of the etching composition.

### [Other Components]

The etching composition of the present invention may contain, in addition to the above components, one or more additives normally used in an etching composition, if necessary, to the extent that the effect of the etching composition described above is not impaired.

In addition, a small amount of alkali may be added as long as the pH does not change significantly.

Furthermore, a known hydrogen peroxide stabilizer such as an alcohol, a phenylurea, an organic carboxylic acid, or an organic amine compound, and an etching rate adjuster, etc. may be added to the etching composition of the present invention as needed.

The etchant of the present invention is preferably a solution, and does not contain solid particles such as abrasive particles.

### [Preparation of Etching Composition]

The etching composition of the present invention can be prepared by homogeneously stirring and mixing components (A), (B), (C), (D), (E) and (F) and other components that are added as needed. The stirring method for mixing these components is not particularly limited, and any stirring method normally used in the preparation of etching compositions can be used.

### [Applications of Etching Composition]

The etching composition of the present invention can be used as an etching composition for selectively etching a copper seed layer from a substrate having a copper wiring pattern and the copper seed layer.

The copper seed layer that is selectively etched by the etching composition of the present invention is preferably an electrolytic copper foil, an electrolytic copper plating film, an electroless copper plating film, or any combination of two or more of them.

Herein, “selectively” means that the etching rate of the copper seed layer is higher than that of the copper wiring.

For example, according to the present invention, the ratio of the etching rate of the copper wiring to that of the copper seed layer can be evaluated by the etching rate ratio with respect to the wiring height and the etching rate ratio with respect to the wiring width of the copper wiring based on the etching rate of the copper seed layer at a process temperature of 30° C. The etching rate ratio with respect to the wiring height and the etching rate ratio with respect to the wiring width are defined by the following formulae (1) and (2):

Etching rate ratio with respect to wiring height=ΔHeight/Thickness of seed layer (1)

Etching rate ratio with respect to wiring width=ΔWidth on one side/Thickness of seed layer (2)
wherein thickness of seed layer refers to the thickness (μm) of the copper seed layer removed by etching, Δheight refers to the etch thickness (μm) of the top surface of the copper wiring removed by etching after the just etching time, i.e., the exact time required to completely remove the copper seed layer by etching, and Δwidth on one side refers to the value (μm) obtained by converting the width of the copper wiring removed by etching after the just etching time, i.e., the exact time required to completely remove the copper seed layer by etching, into the width on one side (½).

According to the present invention, the etching rate ratio with respect to the wiring height is preferably 1.2 or less. Furthermore, the etching rate ratio with respect to the wiring width is preferably 1.4 or less, and more preferably 1.0 or less. According to the present invention, it is preferable that the etching rate ratio with respect to the wiring height satisfies the above range, and it is more preferable that both the etching rate ratio with respect to the wiring height and the etching rate ratio with respect to the wiring width satisfy the above ranges.

For example, the etching composition of the present invention can be advantageously used in SAP or M-SAP for removing a copper seed layer exposed by the removal of a resist pattern after forming a copper wiring pattern. Alternatively, the etching composition of the present invention can be advantageously used in ETS process for removing an electrolytic copper foil, i.e., a copper seed layer.

According to a preferred aspect of the present invention, by etching a copper seed layer using the etching composition of the present invention, it is possible to selectively remove the copper seed layer while suppressing the thinning of the copper wiring and retaining the rectangularity of the wiring cross-section.

While the thickness of the copper seed layer suitable for the removal by the etching composition of the present invention is not particularly limited, it is usually 1.5-15 μm, preferably 1.5-10 μm, and more preferably 1.5-5 μm.

### 2. Method for Producing Wiring Board

A method for producing a wiring board according to the present invention is characterized by comprising a step of selectively etching a copper seed layer from a substrate having a copper wiring pattern and the copper seed layer using the etching composition described above.

The etching composition and the copper seed layer targeted for etching are as described in “1. Etching composition” above.

While the temperature at which the etching composition of the present invention is used is not particularly limited, it is preferably a temperature of 10-50° C., more preferably 20-45° C., and still more preferably 25-40° C. If the temperature of the etching composition is 10° C. or higher, a good etching rate can be achieved, resulting in excellent production efficiency. On the other hand, if the temperature of the etching composition is 50° C. or lower, the change in the liquid composition can be suppressed and the etching conditions can be kept constant. While the etching rate increases as the temperature of the etchant is increased, the optimal process temperature can be determined appropriately considering factors such as minimizing the change in the etchant composition (decomposition of hydrogen peroxide).

Furthermore, while the time of the etching process is not particularly limited, it is preferably 1-600 seconds, more preferably 5-300 seconds, still more preferably 10-180 seconds, and particularly preferably 15-120 seconds. The process time can be suitably selected according to various conditions such as the process temperature and the process method.

The method of bringing the etching composition into contact with an etching object including a copper seed layer is not particularly limited. For example, a wet etching method can be employed, such as a method in which the etching composition in the form of droplets (single-wafer spin treatment) or a spray is brought into contact with an etching object, or a method in which an etching object is immersed in the etching composition. According to the present invention, any method can be employed.

A method for producing a wiring board according to the present invention is suitable, for example, for forming a wiring circuit by selectively etching a copper seed layer from a substrate having a copper wiring pattern and the copper seed layer in semi-additive process (SAP), modified semi-additive process (M-SAP), or embedded trace substrate process (ETS process), using the above etching composition.

Hereinafter, an example of the method for producing a wiring board according to the present invention will be described, although the method for producing a wiring board according to the present invention is not limited to this example.

### <Method for Producing Wiring Board Employing SAP>

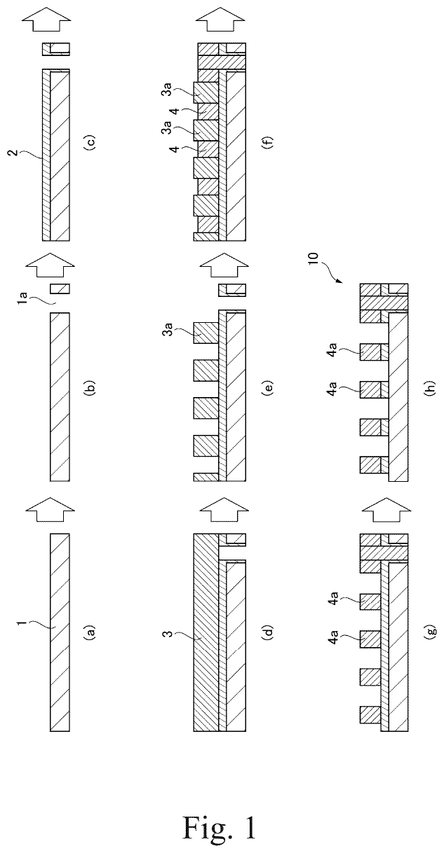

FIG. 1 is a view illustrating a method for producing a wiring board, the method comprising forming a wiring circuit by selectively etching a copper seed layer from a substrate having a copper wiring pattern and the copper seed layer in SAP. In FIG. 1, only structures necessary for illustration are shown schematically.

First, an insulating resin substrate (1) is prepared (FIG. 1(a)), and if necessary, a via or trench (1a) is formed by drilling, etc. (FIG. 1(b)). Next, electroless copper plating is applied to the surface of the insulating resin substrate (1) including the inner wall of the via or trench (1a) to form an electroless copper plating film (2) as a copper seed layer (FIG. 1(c)). Although not shown in the figure, an electrolytic copper plating film may be further formed on the surface of the electroless copper plating film (2). In a case where an electrolytic copper plating film is formed, the electroless copper plating film (2) and the electrolytic copper plating film are referred to as a “copper seed layer”.

Next, a dry film resist (3) is formed on the surface of the electroless copper plating film (2), or the electrolytic copper plating film if an electrolytic copper plating film is formed (FIG. 1(d)), and the resultant is exposed and developed to form a resist pattern (3a) (FIG. 1(e)).

Subsequently, electrolytic copper plating is applied to the copper seed layer between the resist pattern (3a) to form an electrolytic copper plating film (4) (FIG. 1(f)).

Then, the resist pattern (3a) is peeled off with a release solution to form a copper wiring pattern (4a) (FIG. 1(g)).

Finally, the etching composition of the present invention is applied to the surface of the copper seed layer to remove the exposed portions of the copper seed layer, thereby producing a wiring board (10) with a copper wiring pattern (4a) (FIG. 1(h)).

According to a preferred aspect of the present invention, by etching the copper seed layer in SAP using the etching composition of the present invention, it is possible to selectively etch the copper seed layer while suppressing side etching and/or etching of the top surface of the copper wiring pattern (4a) and retaining the rectangularity of the wiring cross-section, thereby producing a wiring board (10) that is compatible with miniaturization of wiring.

### <Method for Producing Wiring Board Employing M-SAP>

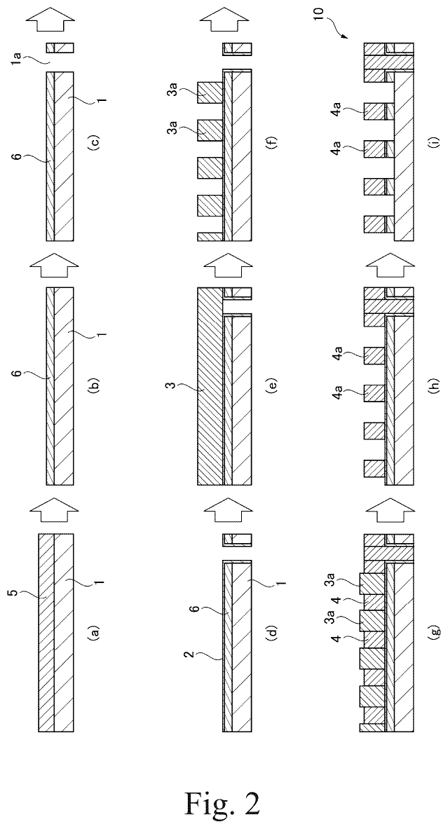

FIG. 2 is a view illustrating a method for producing a wiring board, the method comprising forming a wiring circuit by selectively etching a copper seed layer from a substrate having a copper wiring pattern and the copper seed layer in M-SAP. In FIG. 2, only structures necessary for illustration are shown schematically.

First, an insulating resin substrate (1) is prepared, and an electrolytic copper foil with a carrier foil (not shown) is used to laminate an electrolytic copper foil (5) on the insulating resin substrate (1) (FIG. 2(a)). Examples of the carrier foil include an aluminum foil, a copper foil, a stainless steel foil, a resin film, a resin film with metal coating on its surface, and a glass plate. After the carrier foil is peeled off and removed, if necessary, half etching is performed on the electrolytic copper foil (5) to form a thin copper layer (6) (FIG. 2(b)), and if necessary, a via or trench (1a) is formed by drilling, etc. (FIG. 2(c)).

Next, electroless copper plating is applied to the thin copper layer (6) including the inner wall of the via or trench (1a) to form an electroless copper plating film (2) (FIG. 2(d)). Although not shown in the figure, an electrolytic copper plating film (not shown) may be further formed on the electroless copper plating film (2). In a case where an electrolytic copper plating film is not formed, the thin copper layer (6) and the electroless copper plating film (2) are referred to as a “copper seed layer”. In a case where an electrolytic copper plating film is formed, the thin copper layer (6), the electroless copper plating film (2), and the electrolytic copper plating film are referred to as a “copper seed layer”.

Next, a dry film resist (3) is formed on the surface of the electroless copper plating film (2), or the electrolytic copper plating film (not shown) if an electrolytic copper plating film is formed (FIG. 2(e)), and the resultant is exposed and developed to form a resist pattern (3a) (FIG. 2(f)).

Subsequently, electrolytic copper plating is applied to the copper seed layer between the resist pattern (3a) to form an electrolytic copper plating film (4) (FIG. 2(g)).

Then, the resist pattern (3a) is peeled off with a release solution to form a copper wiring pattern (4a) (FIG. 2(b)).

Finally, the etching composition of the present invention is applied to the surface of the copper seed layer to remove the exposed portions of the copper seed layer, thereby producing a wiring board (10) with a copper wiring pattern (4a) (FIG. 2(i)).

According to a preferred aspect of the present invention, by etching the copper seed layer in M-SAP using the etching composition of the present invention, it is possible to selectively etch the copper seed layer while suppressing side etching and/or etching of the top surface of the copper wiring pattern (4a), thereby producing a wiring board (10) that is compatible with miniaturization of wiring.

### <Method for Producing Wiring Board Employing ETS Process>

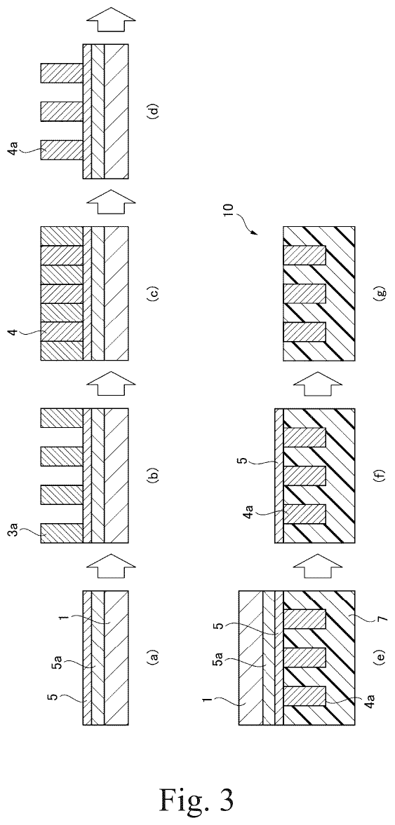

FIG. 3 is a view illustrating a method for producing a wiring board, the method comprising forming a wiring circuit by selectively etching a copper seed layer from a substrate having a copper wiring pattern and the copper seed layer in ETS process. In FIG. 3, only structures necessary for illustration are shown schematically.

First, an electrolytic copper foil (5) with a carrier foil (5a) is laminated on an insulating resin substrate (1) (FIG. 3(a)). Examples of the carrier foil (5a) include an aluminum foil, a copper foil, a stainless steel foil, a resin film, a resin film with metal coating on its surface, and a glass plate.

Next, a dry film resist is formed on the surface of the electrolytic copper foil (5), and the resultant is exposed and developed to form a resist pattern (3a) (FIG. 3(b)). In ETS process, the electrolytic copper foil (5) plays the role of a copper seed layer,

Thereafter, electrolytic copper plating is applied to the exposed area of the electrolytic copper foil (5) where the resist pattern (3a) is not formed, thereby forming an electrolytic copper plating film (4) (FIG. 3(c)).

Then, the resist pattern (3a) is peeled off with a release solution to form a copper wiring pattern (4a) consisting of copper wiring (FIG. 3(d)),

Next, the resulting structure is reversed to embed the copper wiring pattern (4a) in an interlayer insulating resin (7) (FIG. 3(e)). The interlayer insulating resin (7) is not particularly limited as long as it is generally used for producing printed wiring boards.

Then, the insulating resin substrate (1) and the carrier foil (5a) are peeled off (FIG. 3(f)), and finally, the electrolytic copper foil (5) is etched back using the etching composition of the present invention to obtain a printed wiring board (10) with an embedded copper wiring pattern (4a) (FIG. 3(g)).

According to a preferred aspect of the present invention, by etching the electrolytic copper foil (copper seed layer) in ETS process using the etching composition of the present invention, it is possible to selectively etch the electrolytic copper foil (5) while suppressing the occurrence of side etching of the copper wiring pattern (4a) along the sidewall of the interlayer insulating resin (7) and/or etching of the top surface of the copper wiring pattern (4a) and retaining the rectangularity of the wiring cross-section, thereby producing a printed wiring board (10) that is compatible with miniaturization of wiring.

### EXAMPLES

Hereinafter, the present invention will be described in more detail by way of examples and comparative examples, although the present invention is in no way limited to these examples.

### Examples 1-24

### (1) Preparation of Etching Compositions

Components were mixed and stirred homogeneously in the composition ratios shown in Table 1A to prepare etching compositions.

TABLE 1A

| | Etching composition: Remainder water | | | | | | | | Hydrogen |
|---|---|---|---|---|---|---|---|---|---|
| | Hydrogen | Sulfuric | Azole or salt | | Glycol | | Halide | | peroxide/ |
| | peroxide (A) | acid (B) | thereof (C) | | ether (D) | | ion (E) | | sulfuric acid |
| No. | [mass %] | [mass %] | Type | [ppm] | Type | [ppm] | Source | [ppm] | molar ratio |
| 1 | 6 | 4 | Benzimidazole | 2,000 | Diethylene glycol | 3,000 | Sodium | 1 | 4.3 |
| | | | | | monomethyl ether | | chloride | | |
| | | | | | (DGME) | | | | |
| 2 | 3 | 2 | ↑ | 1,000 | ↑ | 1,500 | ↑ | 0.5 | 4.3 |
| 3 | 5 | 2.5 | ↑ | 2,000 | ↑ | 3,000 | ↑ | 1 | 5.8 |
| 4 | 5 | 2.5 | ↑ | 2,000 | ↑ | 3,000 | ↑ | 1 | 5.8 |
| 5 | 10 | 2 | ↑ | 1,000 | ↑ | 1,500 | ↑ | 1 | 14.4 |
| 6 | 0.5 | 0.6 | ↑ | 1,000 | ↑ | 1,500 | ↑ | 0.05 | 2.4 |
| 7 | 6 | 5 | ↑ | 1,000 | ↑ | 1,500 | ↑ | 0.5 | 3.5 |
| 8 | 2 | 0.5 | ↑ | 1,000 | ↑ | 1,500 | ↑ | 0.2 | 11.5 |
| 9 | 5 | 2.5 | ↑ | 5,000 | ↑ | 1,500 | ↑ | 0.5 | 5.8 |
| 10 | 3 | 2 | ↑ | 100 | ↑ | 1,500 | ↑ | 0.5 | 4.3 |
| 11 | 2 | 2.8 | ↑ | 1,000 | ↑ | 1,500 | ↑ | 0.5 | 2.1 |
| 12 | 5 | 2.5 | ↑ | 1,000 | ↑ | 10,000 | ↑ | 0.5 | 5.8 |
| 13 | 5 | 2.5 | ↑ | 1,000 | ↑ | 100 | ↑ | 0.5 | 5.8 |
| 14 | 5 | 2.5 | ↑ | 1,000 | ↑ | 1,500 | ↑ | 0.5 | 5.8 |
| 15 | 5 | 2.5 | 1-Methylbenzimidazole | 2,000 | ↑ | 1,500 | ↑ | 1 | 5.8 |
| 16 | 5 | 2.5 | 2-Methylbenzimidazole | 2,000 | ↑ | 1,500 | ↑ | 1 | 5.8 |
| 17 | 5 | 2.5 | 5-Methylbenzimidazole | 2,000 | ↑ | 1,500 | ↑ | 1 | 5.8 |
| 18 | 5 | 2.5 | 2,5-Dimethylbenzimidazole | 2,000 | ↑ | 1,500 | ↑ | 1 | 5.8 |
| 19 | 5 | 2.5 | 5-Nitrobenzimidazole nitrate | 1,443 | ↑ | 1,500 | ↑ | 1 | 5.8 |
| 20 | 3 | 2 | 4-Methyl-2-phenylimidazole | 1,000 | ↑ | 1,500 | ↑ | 0.5 | 4.3 |
| 21 | 3 | 2 | Pyrazole | 1,000 | ↑ | 1,500 | ↑ | 0.5 | 4.3 |
| 22 | 5 | 2.5 | Benzimidazole | 2,000 | Diethylene glycol | 1,000 | ↑ | 1 | 5.8 |
| | | | | | monophenyl ether | | | | |
| | | | | | (DGPE) | | | | |
| 23 | 5 | 2.5 | ↑ | 2,000 | Ethylene glycol | 1,000 | ↑ | 1 | 5.8 |
| | | | | | monobutyl ether | | | | |
| | | | | | (BG = butoxyethanol) | | | | |
| 24 | 5 | 2.5 | ↑ | 2,000 | Dipropylene glycol | 1,000 | ↑ | 1 | 5.8 |
| | | | | | monomethyl ether | | | | |
| | | | | | (MFDG) | | | | |

### (2) Evaluation Samples

### <Sample for Evaluation in M-SAP (Examples 1-13, Examples 15-24, and Comparative Examples 1-9>

A sample for the evaluation of the etching compositions of Examples 1-13, Examples 15-24, and Comparative examples 1-9 was prepared as follows.

First, an ultra-thin copper foil with a carrier foil “MicroThin 18EX” (provided by Mitsui Mining & Smelting Co., Ltd.) having an electrolytic copper foil thickness of 3 μm was laminated on an insulating resin substrate (detach core) such that the electrolytic copper foil side makes contact thereto.

The carrier foil was then peeled off, and electroless copper plating (0.6 μm) and electrolytic copper plating (3.4 μm) were applied in a total thickness of 4 μm to the exposed electrolytic copper foil to form a 7 μm-thick copper seed layer.

A dry film resist was then laminated on the copper seed layer, and the dry film resist was exposed to have a wiring design with a line/space (L/S)=45/15 μm. The dry film resist after the exposure was developed using an aqueous sodium carbonate solution to form a resist pattern.

Electrolytic copper plating was then applied to the exposed area of the copper seed layer where it was not covered with the resist to form an electrolytic copper plating film with a wiring height of 20 μm.

The resist pattern was then peeled off using dry film release solution “R-100S” (provided by Mitsubishi Gas Chemical Company, Inc.) to obtain a board with copper wiring formed on the copper seed layer (sample for evaluation).

The copper wiring width of the evaluation sample was 43.8 μm and the copper wiring height from the top surface of the copper seed layer was 21.3 μm.

### <Sample for Evaluation in ETS Process (Example 14)>

A sample for the evaluation of the etching composition of Example 14 was prepared as follows.

First, an ultra-thin copper foil with a carrier foil “MT18SD-H-TS” (provided by Mitsui Mining & Smelting Co., Ltd.) having an electrolytic copper foil thickness of 5 μm was laminated on a 100 μm-thick detach core (base material: “HL-832NSF”) (provided by Mitsubishi Gas Chemical Company, Inc.) such that the carrier foil side makes contact thereto.

A dry film resist was then laminated on the surface of the electrolytic copper foil, and the dry film resist was exposed to have a wiring design with a line/space (L/S)=10/10 um. The dry film resist after the exposure was developed using an aqueous sodium carbonate solution to form a resist pattern.

Electrolytic copper plating was then applied to the exposed area of the electrolytic copper foil (copper seed layer) where it was not covered with the resist to form an electrolytic copper plating film with a wiring height of 10 μm.

The resist pattern was then peeled off using dry film release solution “R-100S” (provided by Mitsubishi Gas Chemical Company, Inc.) to form copper wiring on the electrolytic copper foil.

The resulting structure was then revered and laminated such that the copper wiring was embedded in prepreg “GHPL-830NS SH65” (provided by Mitsubishi Gas Chemical Company, Inc.). The outer copper foil laminated on the prepreg on the opposite side from the copper wiring, which was used when laminating the copper wiring on the prepreg, was an ultra-thin copper foil with a carrier foil “MT18Ex” (provided by Mitsui Mining & Smelting Co., Ltd.) having an electrolytic copper foil thickness of 5 μm with the electrolytic copper foil on the prepreg side.

The detach core and the carrier foil were then peeled off to produce a board with an electrolytic copper foil on the surface and copper wiring embedded therein.

The resulting board had copper wiring with a pitch of 20 μm and a wiring width of 10-10.5 μm.

### (3) Etching Process

The samples for evaluation were subjected to an etching process with a spray etching machine at a process temperature of 30° C. using the etching compositions prepared in (1) above. The spray pressure was 0.05 MPa in Example 4 and 0.15 MPa in the rest of the examples and comparative examples. The end point of etching was the time when the copper residue in the copper seed layer between the copper wiring was gone (just etching time), as observed with an optical microscope (“MX-63L” provided by Olympus Corporation).

The sample for evaluation was taken out from the etching composition and washed by immersing in ultrapure water for 10 seconds, 5 mass % sulfuric acid for 10 seconds, and ultrapure water for 10 seconds. The sample for evaluation was removed from ultrapure water and dried by nitrogen blow.

### (4) Evaluation of Width and Height of Copper Wiring After Etching Process

The wiring width and height of the copper wiring after the etching process of the evaluation samples of the examples and comparative examples were measured in the wiring cross-sectional direction using SEM (“S-3700” provided by Hitachi High-Tech Corporation) and evaluated according to the following criteria.

### <Width>

Excellent: 30 μm or more
Good: 25 μm or more but less than 30 μm
Poor: Less than 25 μm

### <Height>

Excellent: 20 μm or more
Poor: Less than 20 μm

### (5) Evaluation of Rectangularity of Copper Wiring After Etching Process

The wiring cross-section of the copper wiring after the etching process was observed using SEM (“S-3700” provided by Hitachi High-Tech Corporation), and the rectangularity of the cross-sectional shape of the wiring was visually evaluated.

Rectangularity was evaluated according to the following criteria.

### <Rectangularity>

Excellent: Rectangularity was retained
Good: Slightly trapezoidal, but retained rectangularity
Poor: Trapezoidal, rectangularity could not be retained, or undercut or side etching occurred.

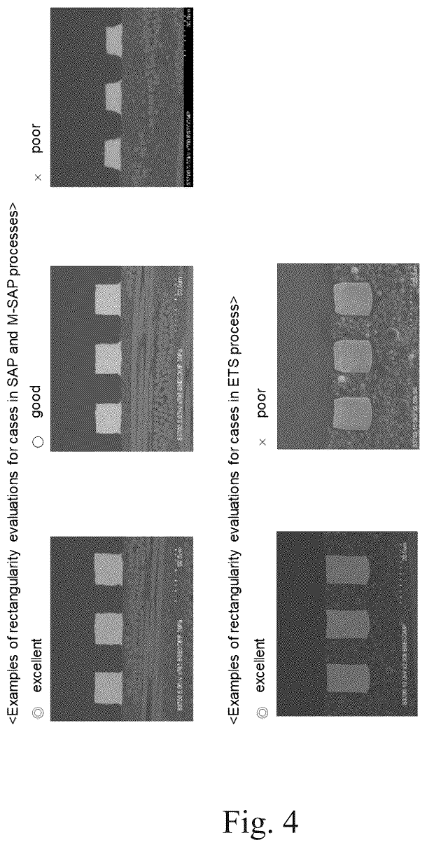

Specific examples of the evaluation criteria are shown in FIG. 4 for the cases in SAP and M-SAP and for the cases in ETS process, respectively.

### (6) Evaluation of Etching Rate of Copper Seed Layer

The etching rate (ER, μm/min) of the copper seed layer was obtained by dividing the thickness of the copper seed layer (μm) by the just etching time (min).

### (7) Evaluation of Etching Rate Ratios

The etching rate ratio with respect to the wiring width and the etching rate ratio with respect to the wiring height were determined according to the following formulae and evaluated according to the following criteria.

Etching rate ratio with respect to wiring height=ΔHeight/Thickness of seed layer (1)

Etching rate ratio with respect to wiring width=ΔWidth on one side/Thickness of seed layer (2)

### <Etching Rate Ratio With Respect to Wiring Height>

Excellent: 1.2 or less
Poor: 1.2 or greater

### <Etching Rate Ratio With Respect to Wiring Width>

Excellent: 1.0 or less
Good: Greater than 1.0 but less than or equal to 1.4
Poor: Greater than 1.4

The results are shown in Table 1B. The poorest rating among the evaluation items was used for the overall evaluation.

TABLE 1B

| | | | | | ΔWidth | | | |
|---|---|---|---|---|---|---|---|---|
| | | | | | on one | | Evaluation of | |
| | | | | ΔWidth/ | side/ | | etching rate | |
| | | | ΔWirth | Thickness | Thickness | | ratio with | |
| | Width | | on one | of seed | of seed | Width | respect to | Height |
| No. | [μm] | ΔWidth | side | layer | layer | evaluation | wiring width | [μm] |
| 1 | 30.8 | 13.0 | 6.5 | 1.9 | 0.93 | Excellent | Excellent | 23.6 |
| 2 | 30.1 | 13.7 | 6.9 | 2.0 | 0.98 | Excellent | Excellent | 22.6 |
| 3 | 28.8 | 15.0 | 7.5 | 2.1 | 1.07 | Good | Excellent | 22.7 |
| 4 | 28.8 | 15.0 | 7.5 | 2.1 | 1.07 | Good | Excellent | 23.2 |
| 5 | 29.4 | 14.4 | 7.2 | 2.1 | 1.03 | Good | Good | 20.0 |
| 6 | 28.8 | 15.0 | 7.5 | 2.1 | 1.07 | Good | Good | 20.6 |
| 7 | 28.5 | 15.3 | 7.7 | 2.2 | 1.09 | Good | Good | 21.3 |
| 8 | 25.8 | 18.0 | 9.0 | 2.6 | 1.29 | Good | Good | 20.6 |
| 9 | 27.9 | 15.9 | 8.0 | 2.3 | 1.14 | Good | Good | 21.8 |
| 10 | 25.5 | 18.3 | 9.2 | 2.6 | 1.31 | Good | Good | 20.0 |
| 11 | 29.2 | 14.6 | 7.3 | 2.1 | 1.04 | Good | Good | 22.2 |
| 12 | 30.5 | 13.3 | 6.7 | 1.9 | 0.95 | Excellent | Excellent | 22.3 |
| 13 | 27.0 | 16.8 | 8.4 | 2.4 | 1.20 | Good | Good | 20.9 |
| 14 | No side etching, good results | | | | | | | |
| 15 | 30.4 | 13.4 | 6.7 | 1.9 | 0.96 | Excellent | Excellent | 26.9 |
| 16 | 31.9 | 11.9 | 5.9 | 1.7 | 0.85 | Excellent | Excellent | 27.7 |
| 17 | 31.4 | 12.4 | 6.2 | 1.8 | 0.89 | Excellent | Excellent | 28.3 |
| 18 | 33.1 | 10.7 | 5.4 | 1.5 | 0.77 | Excellent | Excellent | 28.3 |
| 19 | 31.2 | 12.6 | 6.3 | 1.8 | 0.90 | Excellent | Excellent | 26.5 |
| 20 | 26.5 | 17.3 | 8.7 | 2.5 | 1.24 | Good | Good | 21.6 |
| 21 | 26.3 | 17.5 | 8.8 | 2.5 | 1.25 | Good | Good | 24.7 |
| 22 | 31.9 | 11.9 | 6.0 | 1.7 | 0.85 | Excellent | Excellent | 24.6 |
| 23 | 31.9 | 11.9 | 6.0 | 1.7 | 0.85 | Excellent | Excellent | 24.8 |
| 24 | 31.5 | 12.3 | 6.2 | 1.8 | 0.88 | Excellent | Excellent | 20.8 |

| | | | | Evaluation | | | |
|---|---|---|---|---|---|---|---|
| | | | | of etching | Etching | | |
| | | ΔHeight | | rate ratio | rate of | | |
| | | Thickness | | with respect | copper | | |
| | | of seed | Height | to wiring | seed layer | | Overall |
| No. | ΔHeight | layer | evaluation | height | [μm/mtn] | Rectangularity | evaluation |
| 1 | 4.7 | 0.67 | Excellent | Excellent | 1.9 | Excellent | Excellent |
| 2 | 5.7 | 0.81 | Excellent | Excellent | 3.5 | Good | Good |
| 3 | 5.6 | 0.80 | Excellent | Excellent | 1.5 | Good | Good |
| 4 | 5.1 | 0.73 | Excellent | Excellent | 1.5 | Good | Good |
| 5 | 8.3 | 1.19 | Excellent | Excellent | 6.7 | Good | Good |
| 6 | 7.7 | 1.10 | Excellent | Excellent | 1.2 | Good | Good |
| 7 | 7.0 | 1.00 | Excellent | Excellent | 7.2 | Good | Good |
| 8 | 7.7 | 1.10 | Excellent | Excellent | 4.7 | Good | Good |
| 9 | 6.5 | 0.93 | Excellent | Excellent | 4.0 | Good | Good |
| 10 | 8.3 | 1.19 | Excellent | Excellent | 4.0 | Good | Good |
| 11 | 6.1 | 0.87 | Excellent | Excellent | 1.3 | Good | Good |
| 12 | 6.0 | 0.86 | Excellent | Excellent | 2.5 | Good | Good |
| 13 | 7.4 | 1.06 | Excellent | Excellent | 3.5 | Good | Good |
| 14 | | | | | 3.5 | Excellent | Excellent |
| 15 | 1.4 | 0.20 | Excellent | Excellent | 1.6 | Excellent | Excellent |
| 16 | 0.6 | 0.08 | Excellent | Excellent | 1.9 | Excellent | Excellent |
| 17 | 0.0 | 0.00 | Excellent | Excellent | 1.6 | Excellent | Excellent |
| 18 | 0.0 | 0.00 | Excellent | Excellent | 8.2 | Excellent | Excellent |
| 19 | 1.8 | 0.26 | Excellent | Excellent | 1.8 | Excellent | Excellent |
| 20 | 6.7 | 0.96 | Excellent | Excellent | 2.5 | Good | Good |
| 21 | 3.6 | 0.51 | Excellent | Excellent | 2.3 | Good | Good |
| 22 | 3.7 | 0.53 | Excellent | Excellent | 1.1 | Excellent | Excellent |
| 23 | 3.5 | 0.50 | Excellent | Excellent | 1.9 | Excellent | Excellent |
| 24 | 7.5 | 1.07 | Excellent | Excellent | 1.6 | Excellent | Excellent |

### Comparative Examples 1-9

Etching compositions were prepared in the same manner as in the previous examples, except that the composition ratios were as shown in Table 2A, and etching process was performed using the samples for evaluation to evaluate the shape (width, height, and rectangularity) of the etched copper wiring, the etching rate, and the etching rate ratio.

TABLE 2A

| | | | | | | | | | Hydrogen |
|---|---|---|---|---|---|---|---|---|---|
| | Etching composition: Remainder water | | | | | | | | peroxide/ |
| | Hydrogen | Sulfuric | Azole or salt | | Glycol | | Halide | | sulfuric |
| | peroxide (A) | acid (B) | thereof (C) | | ether (D) | | ion (E) | | acid molar |
| No. | [mass %] | [mass %] | Type | [ppm] | Type | [ppm] | Source | [ppm] | ratio |
| 1 | 0 | 0 | Benzimidazole | 2,000 | DGME | 3,000 | Sodium | 1 | |
| | | | | | | | chloride | | |
| 2 | 5 | 2.5 | — | 0 | — | 0 | — | 0 | 5.8 |
| 3 | 5 | 2.5 | — | 0 | DGME | 3,000 | Sodium | 1 | 5.8 |
| | | | | | | | chloride | | |
| 4 | 5 | 2.5 | Benzimidazole | 2,000 | ↑ | 3,000 | — | 0 | 5.8 |
| 5 | 5 | 2.5 | ↑ | 2,000 | ↑ | 3,000 | Sodium | 10 | 5.8 |
| | | | | | | | chloride | | |
| 6 | 1 | 2.5 | ↑ | 2,000 | ↑ | 3,000 | ↑ | 1 | 1.2 |
| 7 | 5 | 8 | ↑ | 2,000 | ↑ | 3,000 | ↑ | 1 | 1.8 |
| 8 | 4 | 8 | 2-Aminoimidazole | 1,000 | — | 0 | Sodium | 5 | 1.4 |
| | | | | | | | chloride | | |
| 9 | 2 | 9 | 1H-Benzotriazole | 250 | — | 0 | — | 0 | 0.6 |
| | | | 1H-1,2,3-Triazole | 1,000 | | | | | |

The results are shown in Table 2B. The poorest rating among the evaluation items was used for the overall evaluation.

TABLE 2B

| | | | | | ΔWidth | | | |
|---|---|---|---|---|---|---|---|---|
| | | | | | on one | | Evaluation of | |
| | | | | ΔWidth/ | side/ | | etching rate | |
| | | | ΔWirth | Thickness | Thickness | | ratio with | |
| | Width | | on one | of seed | of seed | Width | respect to | Height |
| No. | [μm] | ΔWidth | side | layer | layer | evaluation | wiring width | [μm] |
| 1 | — | — | | — | | — | | — |
| 2 | 25.5 | 18.3 | 9.2 | 2.6 | 1.31 | Good | Good | 16.7 |
| 3 | 28.1 | 15.7 | 7.9 | 2.2 | 1.12 | Good | Good | 19.4 |
| 4 | 21.8 | 22.0 | 11.0 | 3.1 | 1.57 | Poor | Poor | 17.5 |
| 5 | 29.4 | 14.4 | 7.2 | 2.1 | 1.03 | Good | Good | 19.5 |
| 6 | 27.8 | 16.0 | 8.0 | 2.3 | 1.14 | Good | Good | 19.5 |
| 7 | 28.8 | 15.0 | 7.5 | 2.1 | 1.07 | Good | Good | 18.2 |
| 8 | 28.8 | 15.0 | 7.5 | 2.1 | 1.07 | Good | Good | 20.0 |
| 9 | 29.7 | 14.1 | 7.1 | 2.0 | 1.01 | Good | Good | 19.4 |

| | | | | Evaluation | | | |
|---|---|---|---|---|---|---|---|
| | | | | of etching | Etching | | |
| | | ΔHeight | | rate ratio | rate of | | |
| | | Thickness | | with respect | copper | | |
| | | of seed | Height | to wiring | seed layer | | Overall |
| No. | ΔHeight | layer | evaluation | height | [μm/mtn] | Rectangularity | evaluation |
| 1 | — | — | — | | — | — | Poor |
| 2 | 11.6 | 1.66 | Poor | Poor | 10.6 | Good | Poor |
| 3 | 8.9 | 1.27 | Poor | Poor | 3.4 | Good | Poor |
| 4 | 10.8 | 1.54 | Poor | Poor | 9.6 | Good | Poor |
| 5 | 8.8 | 1.26 | Poor | Poor | 0.6 | Good | Poor |
| 6 | 8.8 | 1.26 | Poor | Poor | 0.5 | Good | Poor |
| 7 | 10.1 | 1.44 | Poor | Poor | 2.7 | Good | Poor |
| 8 | 8.3 | 1.19 | Excellent | Excellent | 0.9 | Poor | Poor |
| 9 | 8.9 | 1.27 | Poor | Poor | 2.2 | Poor | Poor |

As can be appreciated from the above results, the etching composition of the present invention can be used to selectively remove the copper seed layer while suppressing the thinning of the copper wiring and retaining the rectangularity of the wiring cross-section (Examples 1-24).

On the other hand, etching did not progress when components (A) and (B) were not contained (Comparative example 1), and the wiring height was greatly reduced and the copper seed layer could not be etched selectively when only components (A) and (B) were contained or when component (C) was not contained (Comparative examples 2 and 3).

Both the wiring width and wiring height were greatly reduced and the copper seed layer could not be etched selectively when component (E) was not contained (Comparative example 4). Moreover, the wiring height was greatly reduced and the copper seed layer could not be etched selectively when the content of component (E) exceeded the specified range (Comparative example 5).

The copper seed layer could not be selectively etched also when components (A)/(B) was below the specified range (Comparative examples 6 and 7).

The rectangularity could not be retained when component (D) was not contained, and components (A)/(B) was below the specified range (Comparative example 8).

The wiring height was greatly reduced and the rectangularity could not be retained when components (D) and (E) were not contained and components (A)/(B) was below the specified range (Comparative example 9).

### Reference Signs List

1 Insulating resin substrate
1a Via or trench
2 Electroless copper plating film
3 Dry film resist
3a Resist pattern
4 Electrolytic copper plating film
4a Copper wiring pattern
5 Electrolytic copper foil
5a Carrier foil
6 Thin copper layer
7 Interlayer insulating resin
10 Wiring board or printed wiring board

1. An etching composition for selectively etching a copper seed layer from a substrate having a copper wiring pattern and the copper seed layer, comprising:
hydrogen peroxide (A); sulfuric acid (B); an azole or a salt thereof (C); a glycol ether (D); a halide ion (E); and water (F), wherein
a content of the hydrogen peroxide (A) is 0.1-10 mass % based on a total amount of the etching composition,
a content of the sulfuric acid (B) is 0.5-5 mass % based on the total amount of the etching composition,
a ratio of the hydrogen peroxide (A) to the sulfuric acid (B) is 2 or greater in terms of a molar ratio, and
a content of the halide ion (E) is 0.01-3 ppm based on the total amount of the etching composition.

2. The etching composition according to claim 1, wherein the azole is a heterocyclic compound having a five-membered heterocyclic ring with two nitrogen atoms or a fused heterocyclic ring thereof.

3. The etching composition according to claim 2, wherein the azole is at least one selected from the group consisting of a pyrazole group, an imidazole group, and a benzimidazole group.

4. The etching composition according to claim 3, wherein the azole is one or more selected from the group consisting of compounds represented by the following formulae: 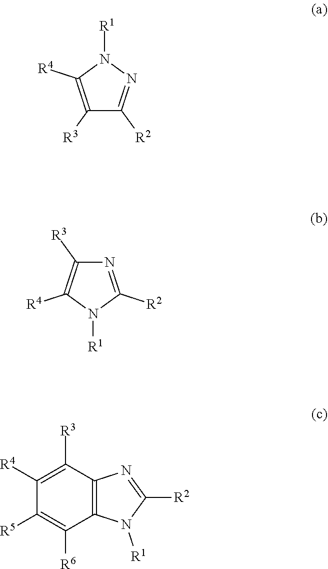
wherein R¹, R², R³, R⁴, R⁵ and R⁶ each independently represent a hydrogen atom, a C₁-C₆ alkyl group, a C₆-C₁₀ aryl group, a carboxyl group, a carboxy C₁-C₆ alkyl group, a nitro group, a hydroxyl group, a C₂-C₇ carboxylic ester, or a halogen atom.

5. The etching composition according to claim 4, wherein the azole is at least one selected from the group consisting of imidazole, 1,2,4,5-tetramethylimidazole, 4-methyl-2-phenylimidazole, benzimidazole, 1-methylbenzimidazole, 2-methylbenzimidazole, 5-methylbenzimidazole, 2,5-dimethylbenzimidazole, 5-nitrobenzimidazole, pyrazole, and 3,5-dimethylpyrazole.

6. The etching composition according to claim 1, wherein the a content of the azole is 0.01-0.5 mass % based on the total amount of the etching composition.

7. The etching composition according to claim 1, wherein the glycol ether (D) is at least one selected from the group consisting of ethylene glycol monobutyl ether, diethylene glycol monomethyl ether, diethylene glycol monophenyl ether, and dipropylene glycol monomethyl ether.

8. The etching composition according to claim 1, wherein a content of the glycol ether (D) is 0.01-1 mass % based on the total amount of the etching composition.

9. The etching composition according to claim 1, wherein the halide ion (E) is a chloride ion.

10. The etching composition according to claim 1, wherein the etching composition is composed to obtain an etching rate ratio with respect to a wiring height of copper wiring as defined by formula (1) at a process temperature of 30° C. of 1.2 or less, when employed to selectively etch a copper seed layer from a substrate having a copper wiring pattern and the copper seed layer:
$$Etching rate ratio with respect to wiring height = Δ Height / Thickness of seed layer \qquad ( 1 )$$
wherein thickness of seed layer refers to a thickness (μm) of the copper seed layer removed by etching, and Δheight refers to an etch thickness (μm) of a top surface of the copper wiring removed by etching after the just etching time, i.e., the exact time required to completely remove the copper seed layer by etching.

11. The etching composition according to claim 10, wherein the etching composition is composed to obtain an etching rate ratio with respect to a wiring width of the copper wiring as defined by formula (2) at a process temperature of 30° C. is of 1.4 or less, when employed to selectively etch a copper seed layer from a substrate having a copper wiring pattern and the copper seed layer:
$$Etching rate ratio with respect to wiring width = Δ Width on one side / Thickness of seed layer \qquad ( 2 )$$
wherein thickness of seed layer refers to a thickness (μm) of the copper seed layer removed by etching, and Δwidth on one side refers to a value (μm) obtained by converting a width of the copper wiring removed by etching after the just etching time, i.e., the exact time required to completely remove the copper seed layer by etching, into the width on one side (½).

12. The etching composition according to claim 1, wherein the copper seed layer is at least one selected from the group consisting of an electrolytic copper foil, an electrolytic copper plating film, and an electroless copper plating film.

13. A method for producing a wiring board, comprising selectively etching a copper seed layer from a substrate having a copper wiring pattern and the copper seed layer with the etching composition according to claim 1.

14. The method for producing a wiring board according to claim 13, wherein the copper seed layer is at least one selected from the group consisting of an electrolytic copper foil, an electrolytic copper plating film, and an electroless copper plating film.

15. A method for producing a wiring board, comprising forming a wiring circuit by selectively etching a copper seed layer from a substrate having a copper wiring pattern and the copper seed layer with the etching composition according to claim 1 in a semi-additive process (SAP), a modified semi-additive process (M-SAP), or an embedded trace substrate process (ETS process).
